(19) United States
(12) Patent Application Publication
(10) Pub. No.: US 2022/0334004 A1
(43) Pub. Date: Oct. 20, 2022

(54) Fiber Optic Temperature Sensor Having Encapsulated Sensing Element

(71) Applicant: Photon Control Inc., Richmond (CA)

(72) Inventors: Hamed AKBARI KHORAMI, Richmond (CA); Michael FEAVER, Richmond (CA); Pranshu Vyomesh SHELAT, Vancouver (CA)

(73) Assignee: Photon Control Inc., Richmond (CA)

(21) Appl. No.: 17/742,877

(22) Filed: May 12, 2022

Related U.S. Application Data
(63) Continuation-in-part of application No. 16/901,951, filed on Jun. 15, 2020.
Application No. 16/901,951 is a continuation-in-part of application No. 16/442,420, filed on Jun. 14, 2019, now abandoned.

(51) Int. Cl. G01K 11/20; G01K 13/00; G01K 3/14; G01K 1/14; H01L 21/67

(52) U.S. Cl. CPC G01K 11/20; G01K 13/00; G01K 3/14; G01K 1/14; H01L 21/67248

(57) ABSTRACT

There is provided a temperature sensor including an optical fiber, and a sensing element spaced from the optical fiber. The sensing element is encapsulated in a optically transparent, non-porous material, isolating the sensing element from a surrounding environment. The optical fiber is aligned with the sensing element to deliver a source beam to interact with the sensing element and detect a return beam, where the return beam exhibits a temperature dependent property that is measured to determine a temperature of a measured object thermally coupled to the sensing element.

### CROSS-REFERENCE TO RELATED APPLICATION(S)

This application is a continuation-in-part of U.S. patent application Ser. No. 16/901,951 filed on Jun. 15, 2020, which is a continuation-in-part of U.S. patent application Ser. No. 16/442,420 filed on Jun. 14, 2019, the contents of which are incorporated herein by reference in their entirety.

### TECHNICAL FIELD

The following is directed to a temperature sensor. In particular, the description is directed to a fiber optic temperature sensor having an encapsulated sensing element.

### BACKGROUND

In semiconductor processing tools, there is a need for temperature control and monitoring to understand and maintain process control. A limited selection of materials can be used within chambers to avoid contamination of the chamber and degradation of the sensor materials exposed to the process environment. In addition, specific applications reach high temperatures and require materials to survive over, e.g., 300° C. Fiber optic temperature sensors used in such applications require careful material selection and unique design considerations. There is also a need for similar temperature sensing, monitoring, and control in other applications beyond semiconductor processing, such as, power, oil and gas, and medical, to name a few.

Fiber optic temperature sensors, such as temperature probes, normally include an optical fiber which can deliver light to a sensing material (e.g., phosphor). The light illuminates the phosphor which, in turn, luminesces visibly or in the near infrared. The temperature of the phosphor can be determined by observing the changes in certain characteristics of the emitted light.

Like temperature sensors, thermographic phosphor sensors do not directly measure temperature but instead measure a physical property that exhibits strong temperature dependence, e.g., phosphorescence time decay. When this property is measured relative to a stable and accurate temperature source, the resulting relationship, or calibration curve can then be used to convert between the measured physical property, e.g., time decay, and temperature, enabling sensor functionality.

Phosphor material used inside temperature sensor probes are often exposed to harsh environments with high temperatures and corrosive chemicals. For example, such probes are often used in systems that use active heating and are exposed to radio frequency (RF) through, e.g., plasma generation, such as plasma deposition processes in a chamber. This results in a change or loss of measurement over time as the phosphor is attacked and degrades. The phosphor should be protected from the environment to ensure long term reliability of the temperature sensor measurement systems. The mechanical design of the probe considers protection of the phosphor from the environment containing at least plasma and fluorine at temperatures up to or above, e.g., 300° C.

Minimizing the difference in temperature between the phosphor and target surface enables more accurate measurement. For contact temperature sensors, this can be achieved by minimizing the heat loss from the contact tip to the body of the probe and maximizing the contact between the tip and the measurement surface.

A unique solution is required to achieve accurate contact temperature measurement at high temperatures in semiconductor process environments. To achieve this, the objective of the design often includes protecting the sensing material from the process environment, reducing the heat loss from the tip to improve contact measurement accuracy, and maximizing the material selection in the high temperature and semiconductor process environment.

Another challenge with temperature measurement is in implementing calibration of an electrostatic chuck (ESC) used to support a wafer to be etched or otherwise interacted with in the chamber. Solutions exist that use temperature sensors on the chuck, e.g., resistance temperature detectors (RTDs) glued to a wafer that is placed on the chuck. However, since RTDs need to be physically wired to the wafer, a feedthrough system is required, increasing the complexity of the chamber. Moreover, should one of the RTDs fail, the entire temperature sensing system would need to be changed. Furthermore, by increasing the number of RTDs used, the number of wires also increases, thus increasing the complexity further.

Another challenge is that environmental factors such as reactive gases, relative humidity, and pressure can adversely affect the sensing material (e.g., phosphor), impacting the sensing material's chemistry and microstructure.

Another challenge with temperature measurement is producing temperature measurement systems (e.g., probes) which have consistent performance between made systems. For example, some processes impose undesirable variability in the performance of the temperature measurement system that require calibration.

All of these issues make the setup of the temperature sensing system fragile, complex, and difficult to scale. While wireless options exist, these are found to be failure prone due to the electronics required. Another option that has been implemented uses radiometry or pyrometry, however, the readings in such a solution can be heavily influenced by the material it is measuring, which can introduce large offsets and limit accuracy.

### SUMMARY

The following pertains to a temperature sensor including an optical fiber, and a sensing element spaced apart from the optical fiber. The sensing element is encapsulated in an optically transparent, non-porous material, isolating the sensing element from a surrounding environment. The optical fiber is aligned with the sensing element to deliver a source beam to interact with the sensing element and detect a return beam, where the return beam exhibits a temperature dependent property of the sensing element that is measured to determine a temperature of a measured object thermally coupled to the sensing element. In one example, the sensing element is intermixed within the optically transparent, non-porous material. In one example, the sensing element comprises a thermographic phosphor.

In another aspect, there is provided a method of encapsulating a sensing material, where the sensing material is a phosphor based sensing material (e.g., a thermographic phosphor). The method includes providing the sensing material and an encapsulating material. The method includes sintering the provided encapsulating material into a optically transparent, non-porous structured material encapsulating the sensing material. In one example, the encapsulating material is glass and the sensing material is a thermographic phosphor.

### BRIEF DESCRIPTION OF THE FIGURES

The features of certain embodiments will become more apparent in the following detailed description in which reference is made to the appended figures wherein:

FIG. 1 is a schematic diagram of a fiber optic temperature sensor providing a gap between an optical fiber and a sensing element.

FIG. 2 is a schematic diagram of a fiber optic temperature sensor providing a gap between an optical fiber and a sensing element with the optical fiber being obliquely aligned with the sensing element.

FIG. 3 is a schematic diagram of a fiber optic temperature sensor providing a gap between an optical fiber and a sensing element with the optical fiber being aligned with a passage in an object between it and the sensing element.

FIG. 4 is a schematic diagram of a fiber optic temperature sensing system having multiple sensors with a gap between a respective optical fiber and a respective sensing element with the optical fibers being aligned with passages in an object between them and the sensing elements.

FIG. 5 is a schematic diagram of a fiber optic temperature probe providing a gap between a probe shaft containing an optical fiber and a sensing tip containing a sensing element.

FIG. 6 is a schematic diagram of a fiber optic temperature sensor for sensing the temperature of an object in a chamber, providing separation between an optical fiber outside of the chamber and a sensing element within the chamber.

FIG. 7 is a schematic diagram of a fiber optic temperature sensing system having multiple sensors with optical fibers aligned with passages through an ESC in a processing chamber.

FIG. 8 is a schematic diagram of a silicon wafer with a phosphor sensing element.

FIG. 9 is a schematic diagram of a system setup for the silicon wafer shown in FIG. 8.

FIG. 10 is a schematic illustration of the temperature probe, optical cable and temperature sensor converter.

FIG. 11 is a schematic illustration further depicting details of the interior components of the temperature sensor converter.

FIG. 12 is a cross-sectional top perspective view of the temperature probe.

FIG. 13 is a cross-sectional view of the temperature probe mounted to a showerhead of a semiconductor deposition chamber.

FIG. 14 is a cross sectional view of the tip.

FIG. 15 is a perspective view of the tip.

FIG. 16 is a cross sectional view of the tip showing an adhesive applied between the window and the body of the tip.

FIG. 17 is a schematic diagram of a fiber optic temperature sensor having encapsulated sensing material.

FIGS. 18A and 18B are each an image of an example encapsulated sensing material.

FIGS. 19A and 19B are, respectively, a top view and a cross sectional view of part of the example encapsulated sensing material of FIG. 18B.

FIGS. 20A and 20B are each a cross-sectional diagram of part of an example temperature probe.

FIG. 21A is a schematic diagram of an example fiber optic temperature sensor having an encapsulated sensing material.

FIG. 21B is a schematic diagram of an example mounted encapsulated sensing material.

FIG. 22 is a diagram of experimental results of the performance of example encapsulated sensing material.

FIG. 23 is a flow chart diagram of an example method of manufacturing an encapsulated sensing material.

FIG. 24 is another diagram of experimental results of the performance of encapsulated sensing material.

### DETAILED DESCRIPTION

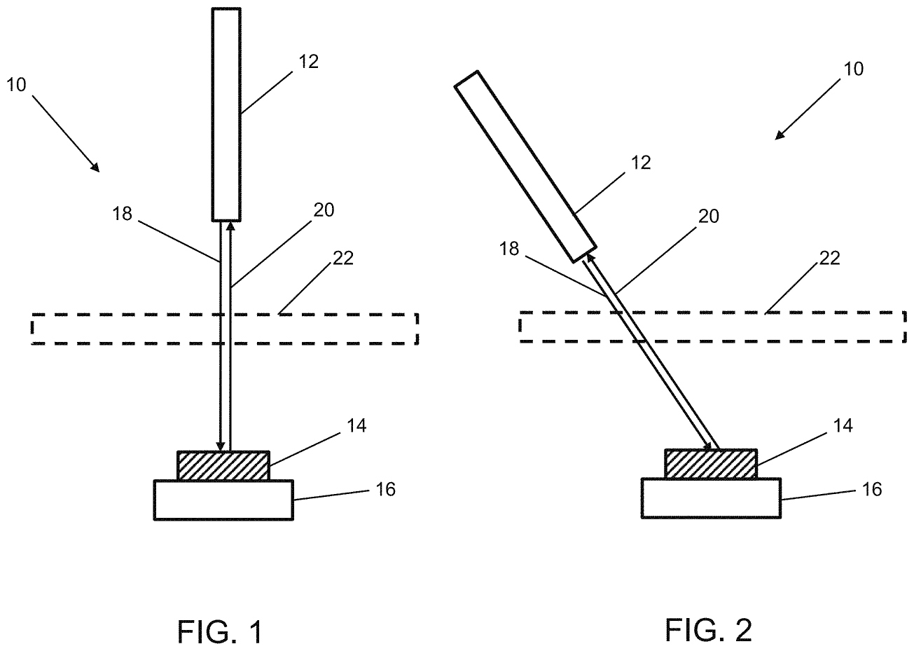

Turning now to the figures, FIG. 1 illustrates a temperature sensor 10 that provides a separation between an optical fiber 12 used as the light source and a sensing element 14 that is used to measure the temperature of a measured object 16. The separation between the optical fiber 12 and the sensing element 14 can be implemented for various purposes as discussed below, for example, to thermally separate a probe tip from a probe shaft, to enable remote temperature sensing of a closed or separated environment such as a chamber, etc. As shown in FIG. 1, the optical fiber 12 can be positioned to direct a source beam 18 towards the sensing element 14 across a boundary 22, and detect a return beam 20 that has interacted with the sensing element 14 to measure the temperature of the measured object 16. The boundary 22 in this example is shown in dashed lines to illustrate that the boundary 22 can take the form of a physical boundary such as an optically transparent “window” or passage, and/or may represent a gap between the optical fiber 12 and the sensing element 14 and any structural element(s) (not shown) that contain or support them. As discussed above, while examples herein may refer to temperature sensing, monitoring and control in semiconductor processing, the principles discussed herein can be applied to any application using such functionality.

FIG. 2 illustrates an alternative arrangement for the sensor 10 wherein the optical fiber 12 is aligned obliquely relative to the boundary 22 such that the beam 18 interacts with the sensing element 14 at an angle. The arrangement shown in FIG. 2 can allow the sensor 10 to be deployed in various applications where straight-line separation is not possible or is difficult. Moreover, the oblique arrangement can be used when the supporting element(s) provide constraints making a straight-line arrangement difficult.

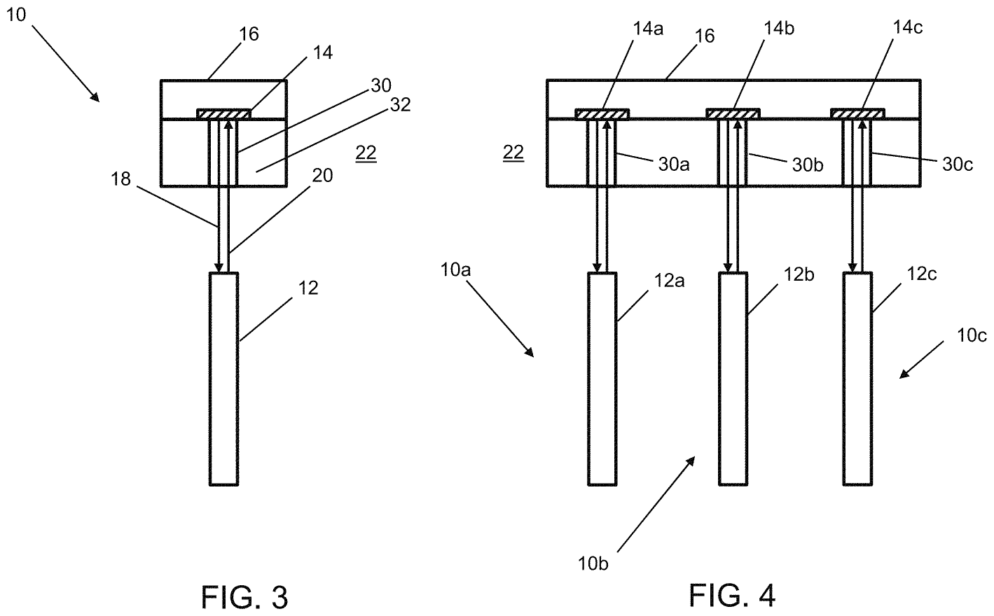

FIGS. 3 and 4 illustrate other forms the boundary 22 may take, namely in which the optical fiber 12 is aligned with a passage 30 in a structural element 32 which is interposed between the optical fiber 12 and the sensing element 14. The arrangement shown in FIGS. 3 and 4 can be implemented in scenarios where temperature sensing is performed from below the measured object 16, e.g., within a plasma chamber. It can be appreciated that this arrangement can also be implemented from above the sensing element 14 and measurement object 16. Moreover, it can be appreciated that while the optical fiber 12 is shown to be positioned at a distance from the passage 30, the optical fiber 12 can also be inserted into the passage 30 or otherwise embedded or secured in the structural element 32.

In FIG. 4, it can be seen that multiple sensors 10a, 10b, 10c (three shown for illustrative purposes only) can be integrated into a temperature measurement system. In this example, a first optical fiber 12a remotely interacts with a first sensing element 14a, and second and third optical fibers 12b, 12c remotely interact with second and third sensing elements 14b, 14c via first, second and third passages 30a, 30b, 30c for measuring at multiple points on the measured object 16. It can be appreciated that this multiple sensor arrangement can also be implemented with the configurations shown in FIGS. 1 and 2. It can also be appreciated that the multiple sensor arrangement can be used to measure multiple measured objects (not shown).

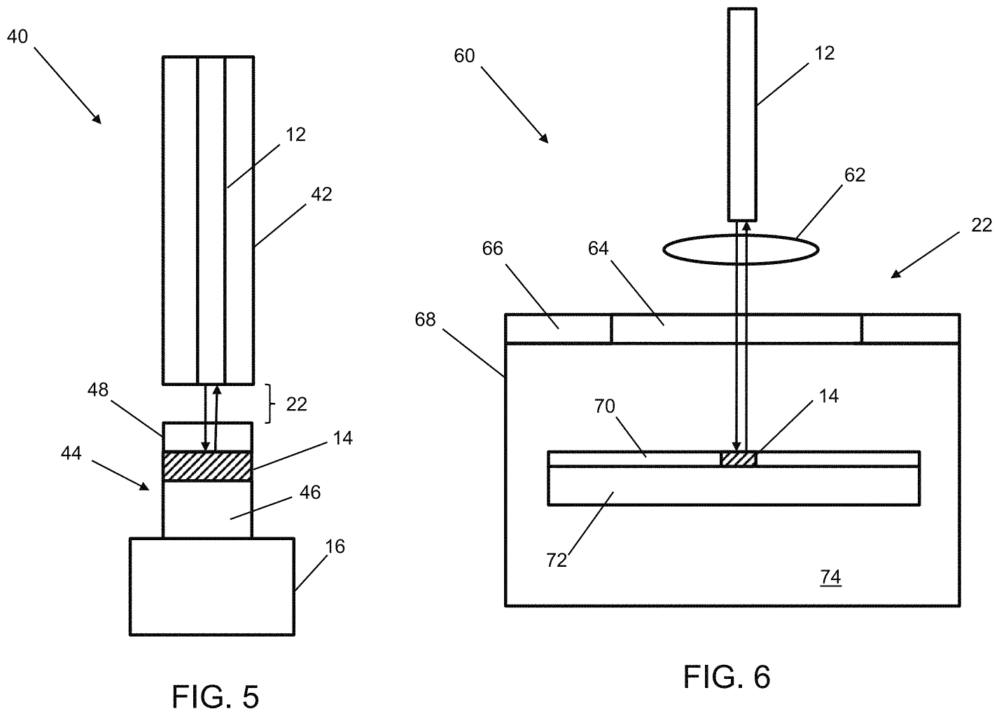

Turning now to FIG. 5, a temperature sensing probe 40 is shown. In this example, the boundary 22 takes the form of a gap between a probe shaft 42 containing the optical fiber 12 and a probe tip 44 that includes an object engaging portion 46, sometimes referred to as a “button”, with a sensing element 14. The sensing element 14 engages the object engaging portion 46 to detect the temperature of the measured object 16. The boundary 22 also includes a window 48 that is used to protect the sensing element 14 in the tip 44.

FIG. 6 illustrates a temperature sensing system 60 for a semiconductor processing chamber 68, wherein the boundary 22 includes a transparent window 64 in a lid 66 of the chamber 68. The optical fiber 12 is positioned outside of the chamber 68 and is aligned with the window 64 to enable the source beam 18 to reach the sensing element 14 that is on or integrated with a silicon wafer 70 supported by an ESC 72. It can be appreciated that details of the interior 74 of the chamber 68 are omitted for ease of illustration. It can also be appreciated that multiple sensing elements 14 and multiple optical fibers 12 can be included in an arrangement such as that shown in FIG. 6, with either a sufficiently wide window 64 or multiple windows 64 in the lid 66 (not shown). Also shown in FIG. 6 is a lens 62 (or lens device or system) that can be used to focus the beam 18 in applications where the distance between the optical fiber 12 and the sensing element 14 requires.

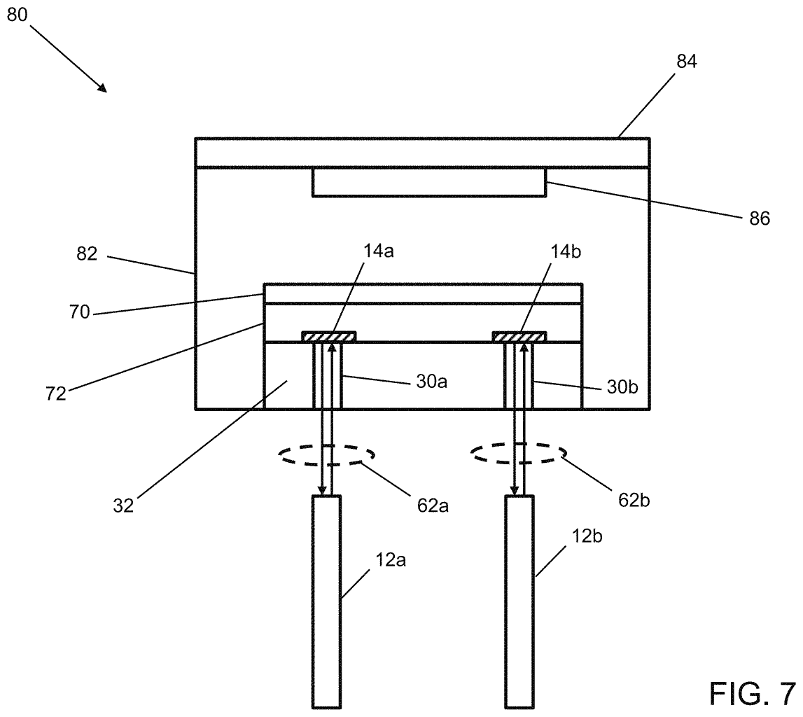

FIG. 7 illustrates another temperature sensing system 80 for a semiconductor processing chamber 82. In this example, an ESC 72 supports a wafer 70 but a pair of sensing elements 14a, 14b are applied or embedded in the underside of the ESC 72. Here a structural element 32 supports the ESC 72 with a pair of passages 30a, 30b aligned with the sensing elements 14a, 14b to enable corresponding optical fibers 12a, 12b to direct source beams 18 at the sensing elements 14a, 14b. If required (as shown in dashed lines) lenses 62a, 62b can also be used to focus the source beams 18. In this example, a showerhead 86 is shown supported beneath a lid 84 of the chamber 82.

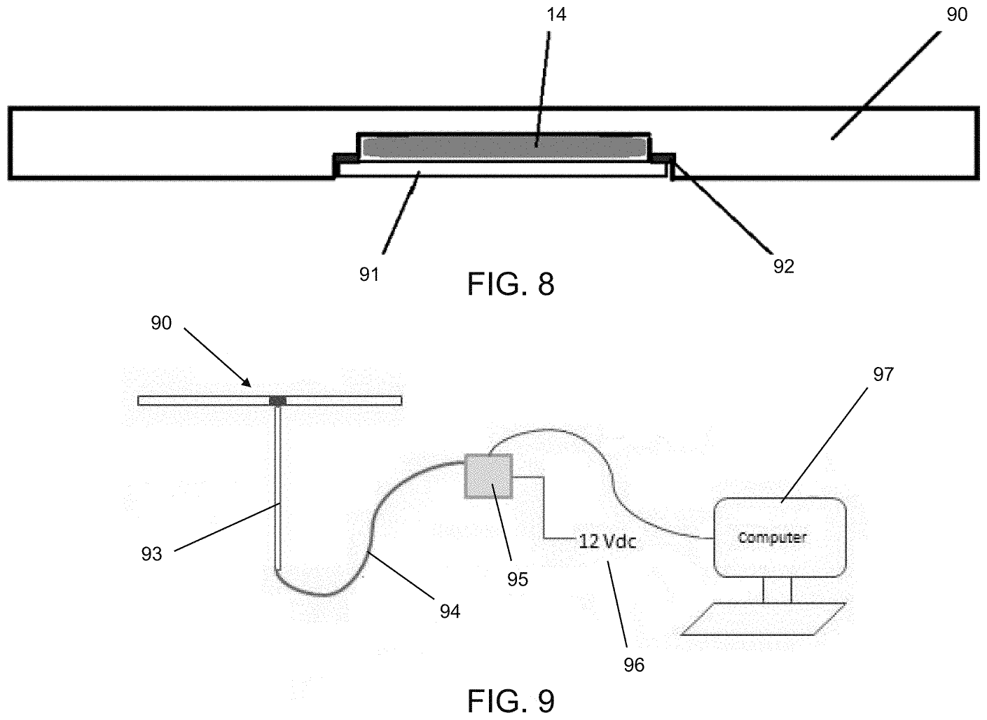

Yet another configuration is shown in FIG. 8 in which a silicon wafer 90 includes a sensing element 14 embedded in its underside, e.g., on a recessed pocket in the silicon water 90 and downwardly facing to interact with the source beam 18 of an optical fiber 12 (not shown). The phosphor sensing element 14 in this example is protected from its environment by a sealing window 91 that is sealed in the recessed pocket using an adhesive 92 or binding joint.

The configuration shown in FIG. 8 enables the temperature of the silicon wafer 90 to be measured using the sensing element 14. An example of a system configuration is shown in FIG. 9, in which a light guide or other light transmission component 93 is positioned adjacent and in alignment with the sensing element 14 on the silicon wafer 90. The component 93 can be a sapphire rod or any other suitable material. The component 93 is coupled to a converter 95 via a cable 94 (e.g., an SMA patch cord). The converter 95 is powered by a power supply 96 (e.g., 12 VDC as illustrated) and can be coupled to a computer 97 or other computing device to enable a temperature sensing operation.

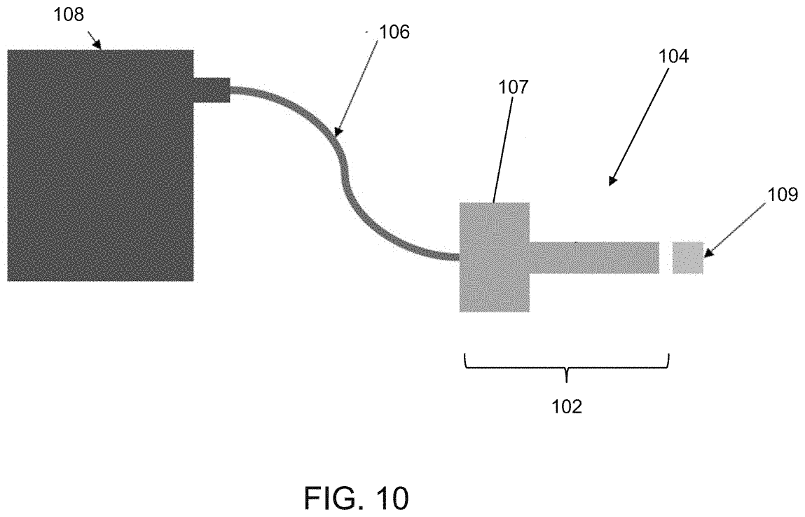

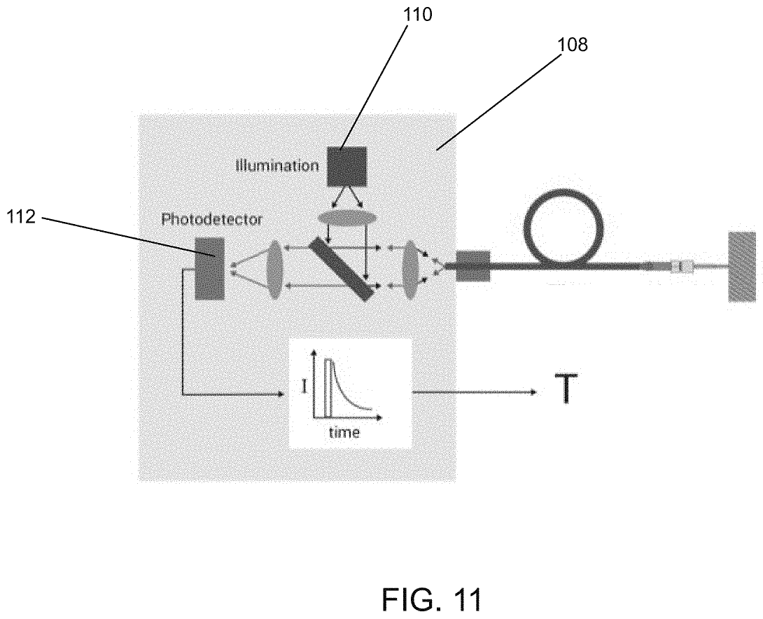

FIGS. 10-16 provide additional detail for the configuration shown in FIG. 5. FIG. 10 shows an optical temperature sensor having a temperature probe 102, comprising a tip 109 and a mount 104. The mount 104 contains a fiber optical cable 106 therein and this fiber optical cable 106 extends out from the mount 104 to optically couple the mount 104 to a temperature sensor converter 108. As illustrated in FIG. 11, the temperature sensor converter 108 contains therein, an illumination device 110 for providing a source beam 18 to be projected down the fiber optical cable 106 and a photodetector 112 to receive a return beam 20.

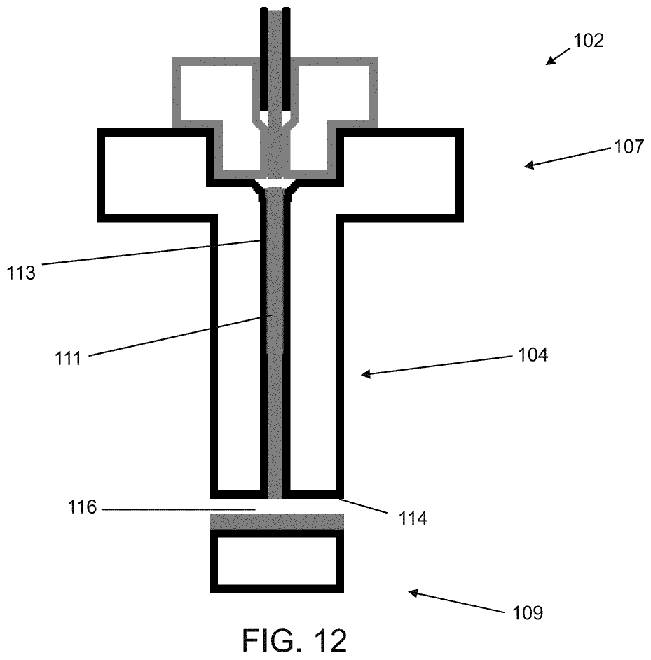

FIG. 12 illustrates a fiber optic temperature sensor 102 having a shaft 104, a tip 109, and a base 107. An optical fiber 111, fed through optical cable 106, run through a channel 113 in the shaft 104 and base 107. Although various types of optical fibers 111 would be known to a person skilled in the art, in an embodiment, the fiber 111 is a fused silica fiber with a silica cladding. While various sizes of fibers would be known, in an embodiment, the fiber has a 1 mm diameter. The optical fiber 111 is exposed at the bottom end 114 of the shaft 104. Below the shaft 104, and spaced from the shaft 104, is the tip 109. Since the tip 109 is spaced from the shaft 104, the space between the shaft 104 and the tip 109 contains the atmosphere of the environment in which the sensor 102 is being used. The space, or gap 116, between the shaft 104 and tip 109 can vary, e.g., approximately, 0.25 to 1.5 mm. By increasing the power of the light source, an increased distance between the optical fiber 111 and the tip 109 can be used.

The optical fiber 111 is held in place by the base 107 and shaft 104, however the illumination device 110, photodetector 112 and means for processing the light and wavelength returning to the temperature sensor converter 108 can be located external to probe 102, as shown in FIG. 11. The optical fiber 111 extends outside the probe 102 as part of optical cable 106. In this way, the light source and means for processing a light signal can be located away from the any harsh environment in which the temperature sensor is being used.

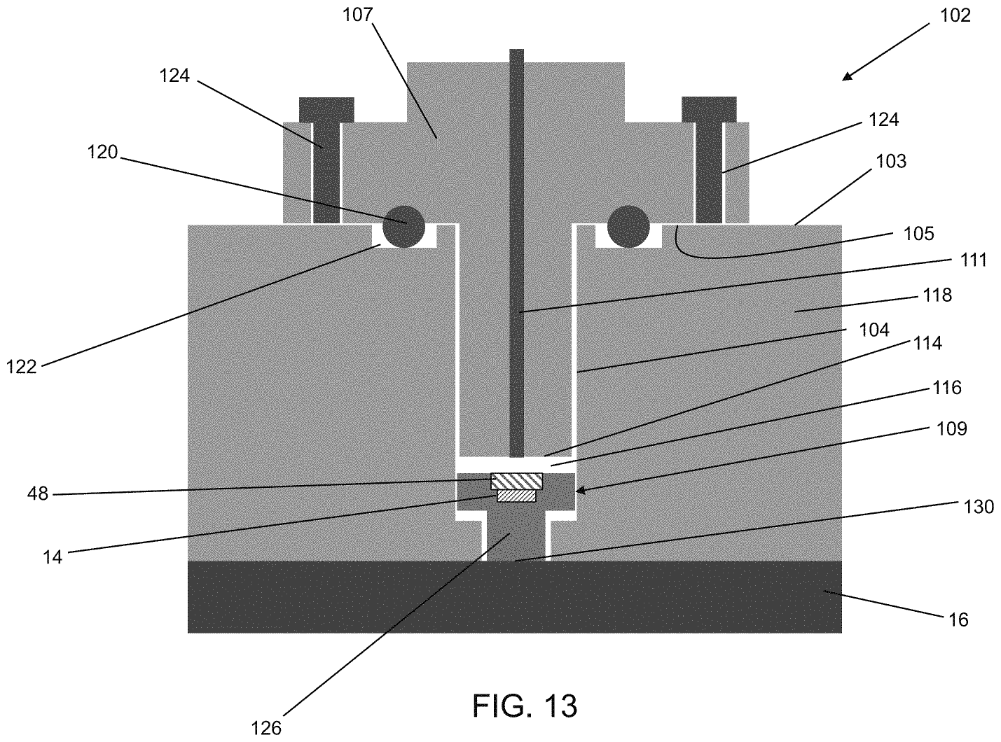

FIG. 13 shows the temperature sensor 102 fixed to the body of a showerhead for use in semiconductor environments. While the temperature sensor 102 described herein could be used in a variety of environments, due to the harsh nature of semiconductor chambers, the temperature sensor 102 has particular advantages for use in semiconductor environments, for example in semiconductor deposition chambers or semiconductor etch chambers. However, it will be appreciated by a person skilled in the art that the temperature sensor 102 could be used in any environment suitable for a contact optical temperature sensor. As such, the design of the base 107 can be varied to be suitable for use in any environment where an optical contact temperature sensor is required.

Returning to FIG. 13, the temperature sensor 102 is coupled to the body of the showerhead 118. In order to maintain a firm seal with the showerhead 118 a sealing device, such as the O-ring 120 is compressed between the top surface 103 of showerhead 118 and the bottom surface 105 of base 107. As can be appreciated, other methods of sealing would be known to a person skilled in the art. This seal is used to maintain the vacuum in the semiconductor chamber. However, in other applications where a sealed air-tight environment is not required, the seal can be omitted. The O-ring 120 sits in groove 122 of the showerhead 118 to provide proper positioning of the O-ring 120 relative to the sensor base 107 and to allow for ease of assembly without the O-ring 120 shifting. The base 107 may then be fixed to the showerhead 118 using screws 124 in this example. Although screws 124 are shown for coupling the base 107 to the showerhead 118, other fastening mechanisms could be used. While only two screws 124 are shown in the figures as points of attachment, it can be appreciated that any suitable number of points of attachment could be used.

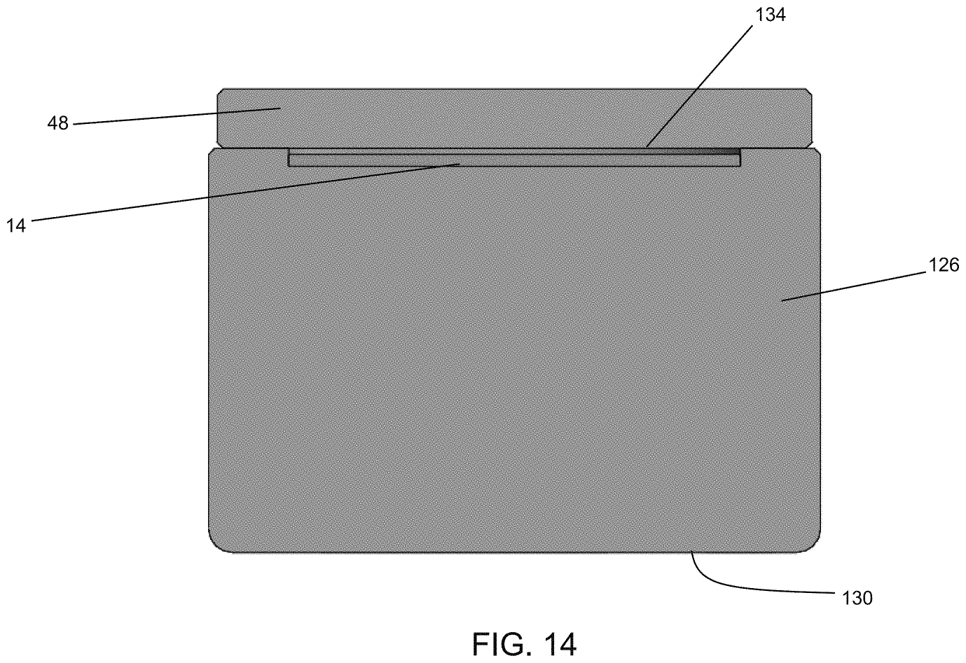

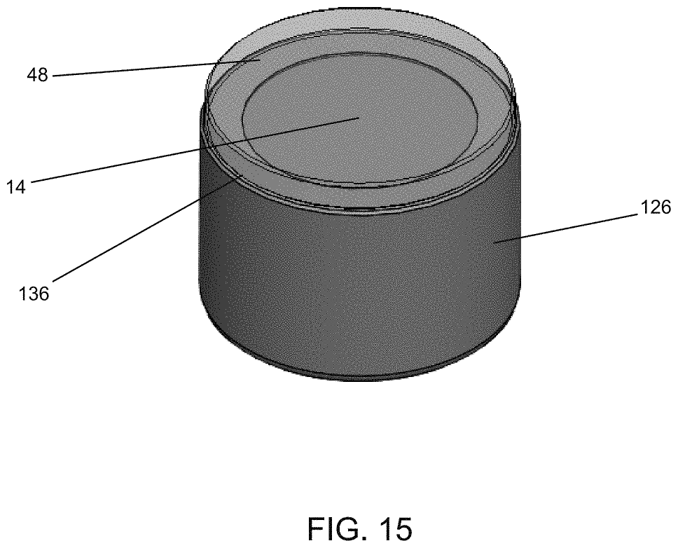

The tip 109, shown in FIGS. 14 and 15, has a body 126 made of a thermally conductive material. In a preferred embodiment, the body 126 is made of alumina. While other suitable materials may be known to a person skilled in the art, alumina allows for good conductivity while being resistant to high temperatures and corrosive environments, such as those in semiconductor deposition chambers containing plasma and other chemicals such as, Fluorine.

Within the tip 109 is a layer of sensing material 14. This sensing material 14 can be phosphorescent such as phosphor, although other materials would be known to a person skilled in the art.

The sensing material 14 is applied onto the thermally conductive tip 109. In order to do this, the sensing material 14 can be mixed with a suitable adhesive. Application of the sensing material 14 and adhesive combination can be done by any suitable method known to a person skilled in the art including, but not limited to deposition, sputtering, bonding, panting, and spin on. The sensing material 14 is excited by light transmitted through the optical fiber 111. As stated above, the body material 126 is thermally conductive to increase the heat flow from the measurement surface 130 of the measured object 16, to the sensing material 14 for more accurate measurement.

The sensing material 14 can be protected from the environment using a window 48 positioned between the sensing material 14 and the gap 116. The window 48 is sealed to the body 126 of the tip 109 using any suitable sealing process that will hermetically seal the window 48 between the body material 126 and the gap 116. An adhesive having high temperature resistance and resistance to radicals can be used. The window 48 is transparent to allow for light to be transmitted from the optical fiber 111 to the sensing material 14. Although a variety of materials could be used for the window 48, a suitable example material is sapphire as it is highly transparent, compatible with the preferred hermetic sealing technique (described below), capable of surviving high temperature environments and resistant to the harsh chemical environment of a semiconductor chamber. Furthermore, sapphire and alumina have similar coefficients of thermal expansion and thus a seal can be maintained between the two even as the temperature changes. In this respect, similar coefficients of thermal expansion can be defined as coefficients of thermal expansion which are sufficiently similar such that when window material and body material expand and contract, the rates and amount of expansion and contraction are not so different as to cause separation between the two. Typically, materials wherein the difference in coefficients of thermal expansion is in the range of 6-10×10⁻⁶° C. or less will be suitable. It can be appreciated by a person skilled in the art that other window and tip materials with similar coefficients of thermal expansion could be used.

As can be seen in FIG. 13, the body 126 of the tip 109 has a shoulder or sealing surface 136 to allow for the sealing of the window 48 to the body 126 without contacting the sensing material 14. The outer edges of the window 48 can be affixed to the body 126 using zinc borosilicate glass due to its ability to adhere to both sapphire and alumina and maintain adhesion in high temperature applications. Although zinc borosilicate glass is used as an adhesive in a preferred embodiment, other adhesives would be known to a person skilled in the art.

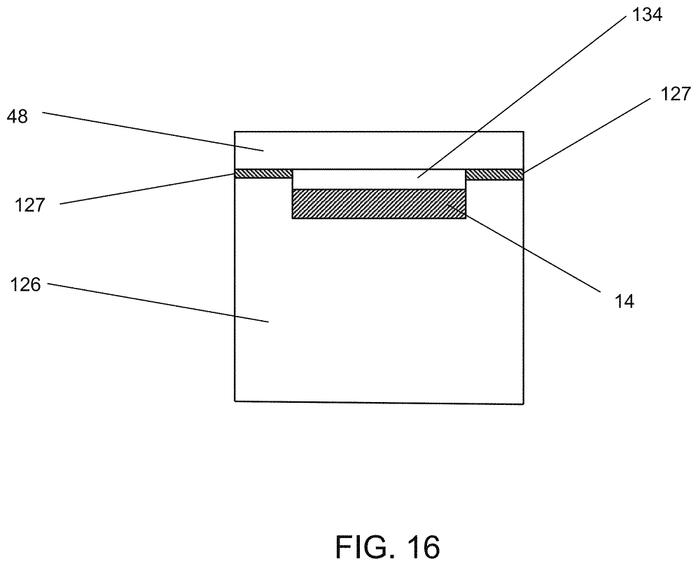

In order to create the hermetic seal, the adhesive, for example zinc borosilicate glass, is heated. For zinc borosilicate glass, it is heated to approximately 400° C. to 700° C. A film of the adhesive can be applied to the sapphire, or alumina, or both the sapphire and alumina, using any suitable method, including, but not limited to, chemical vapor deposition, sputtering, evaporating and spin on. FIG. 16 shows the sealing material 127 between the window 48 and the body 126.

In an embodiment, the application of the glass seal can be screen printed or painted onto the surface. A stencil is made with a geometry adapted to fill the volume of space between the sensing material and the sealing surface. The glass seal is applied, and the stencil is removed. The window is then placed atop the adhesive using a fixture to ensure concentricity between the window to the tip. The entire assembly is then placed in a furnace and baked at atmospheric pressure.

A layer of gas 134, such as air, can be left between the sensing material 14 and the window 48. This layer of gas 134 ensures that the sensing material 14 does not touch the window 48. In this way, the sensing material 14 is inhibited from losing heat to the window 48 which aids in more accurate temperature measurements.

The window 48 can be directly sealed onto the probe tip 109 in which the sensing material 14 is applied. By sealing the window 48 in the probe tip 109, the tip assembly is self contained and can be used for various tip geometries to maximize contact and heat transfer from the measured surface 130.

In an alternative embodiment a transparent coating of sapphire or other suitable material, such as aluminum oxide, is applied on to the upper surface of the body of the tip 126 to completely cover the sensing material 14, isolating the sensing material 14 from the surrounding environment. This could be done with a variety of different methods such as, but not limited to, deposition, screen printing or with a thermal spray coating process.

When in use, the tip 109 can be placed in contact with the measured object 16 for which the temperature reading is required. Since the body 126 of the tip 109 is made of conductive material, the heat flows from the measurement surface 130 through the body 126 of the tip 109 and to the sensing material 14. A source beam 18 from the illumination device (shown in FIG. 11) is provided using the optical fiber 111. The light shines through the transparent window 48 and on to the sensing material 14. The incoming light of the source beam 18 excites the sensing material 14 causing it to emit a wavelength of light (i.e. the return beam 20) back through the window 48 and into the optical fiber 111. This light is transmitted through the optical cable 106 to the temperature sensor converter 108. Since the wavelength emitted by the sensing material 14 is correlated to the temperature of the sensing material 14, the temperature sensor converter 108 uses the wavelength to determine the temperature of the sensing material 14 which is reflective of the temperature of the measurement surface 130. In the embodiment having a tip body material of alumina and a window material of sapphire, temperature can be measured with an accuracy of approximately +/−2° C.

By separating the tip 109 from the shaft 104, heat loss from the tip 109 to the shaft 104 is reduced compared to traditional optical temperature sensors. This improves the accuracy of the measurement by reducing the difference in the temperature of the sensing material 14 and the measurement surface 130. Furthermore, since the optical fiber 111 is spaced from the tip 109, heat transfer from the tip 109 to the optical fiber 111 is reduced. This allows materials which have a lower temperature tolerance to be used to make the optical fiber 111, reducing cost. Furthermore, the number of parts required for assembly can also be reduced. By isolating the sensing material 14 from the surrounding harsh environment, durability of the probe can be increased, and should the tip eventually degrade, it would be possible to replace just the tip 109 as opposed to the entire probe 102.

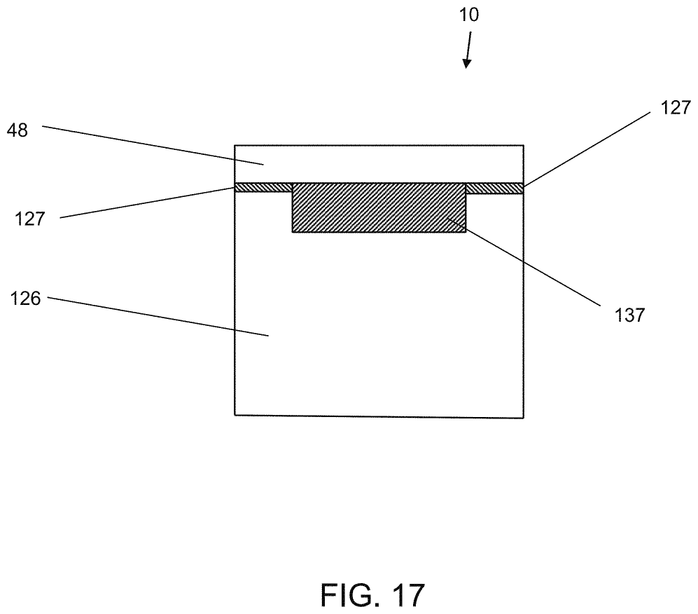

FIG. 17 shows an example embodiment of sensing material within the tip 109 being isolated from the surrounding environment. The sensing material, e.g., sensing material 14, can be encapsulated in a transparent, non porous coating of glass or other suitable encapsulating material. In FIG. 17, the sensing material and the encapsulating material are identified by the reference numeral 137, and hereinafter jointly referred to by as the encapsulated sensing material 137.

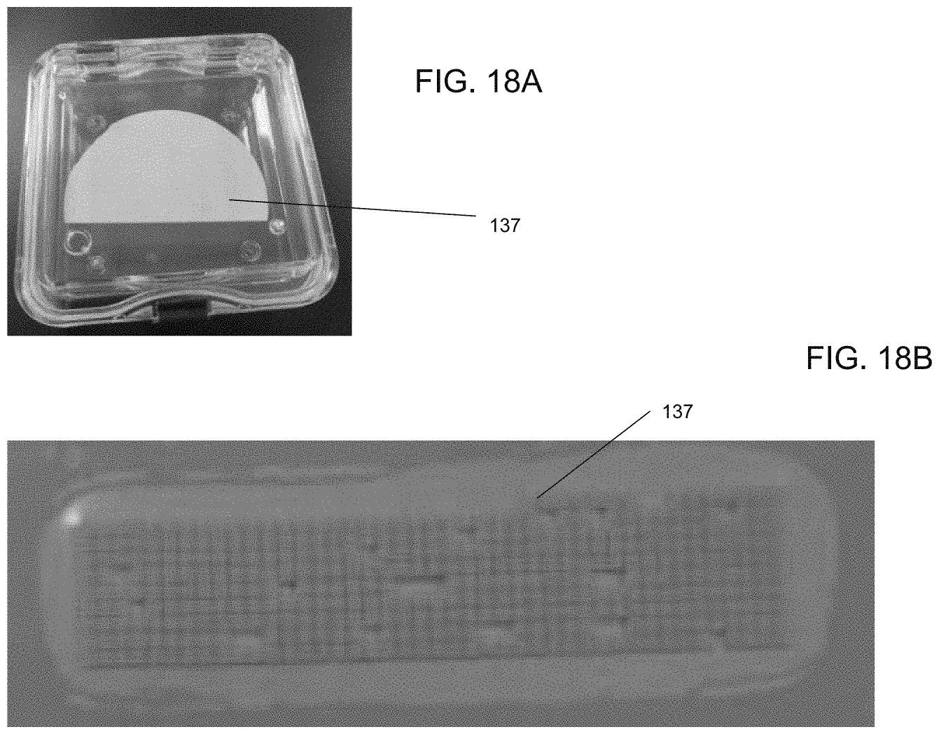

It is understood that the encapsulated sensing material 137 can be a variety of different shapes and sizes, depending on the required application. For example, FIG. 18A shows the encapsulated sensing material 137 as a wafer. The shape or size of the encapsulated sensing material 137 can be further configured or manipulated at various stages of assembly or manufacture. For example, FIG. 18B shows the encapsulated sensing material 137 in a diced wafer shape. The shape can be the result of machining or manipulating the wafer encapsulated sensing material 137.

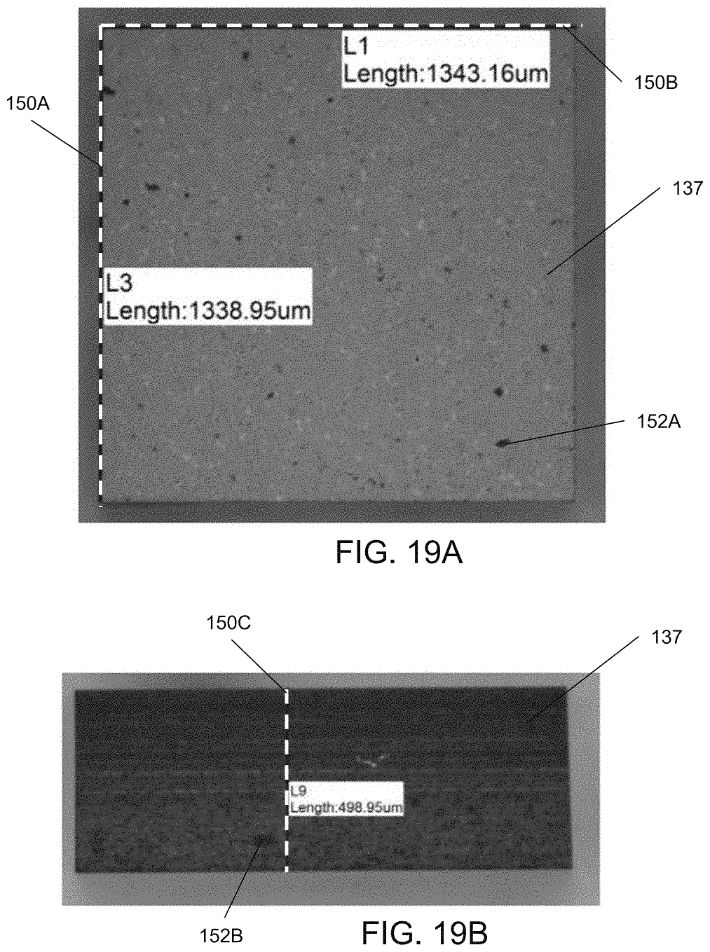

FIGS. 19A, 19B each show magnified images of the structure of an example Thermographic Phosphor in Glass (TPiG) encapsulated sensing material 137. In the top view shown in FIG. 19A (with the field of view of the image defined by a height 150A (1338.95 micrometers) and a length 150B (1343.16 micrometers) of the sample), the potential high hermiticity of the example encapsulated sensing material 137 is shown owing to relatively few black spaces 152A indicative of low hermicity. The cross-sectional view shown in FIG. 19B (with the shown sample having a depth 150C of 498.95 micrometers) similarly shows the potential high hermiticity owing to the relatively few dead spaces 152B in the image.

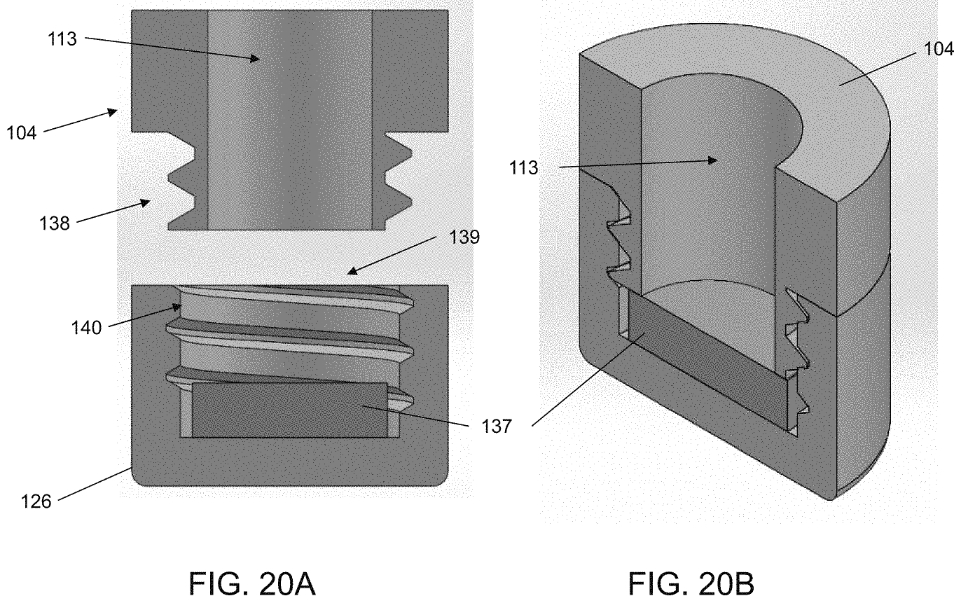

By encapsulating the sensing material 14 into the encapsulated sensing material 137, the sensor 10 may not only isolate the sensing material 14 from the surrounding environment, but may possibly protect the sensing material from physical wear or impact, or allow for rougher or less sensitive handling or assembly. For example, in the embodiment shown in FIGS. 20A, 20B, the encapsulated sensing material 137 can be used in part to define an assembly. In FIGS. 20A, 20B, the channel 113 extending through the shaft 104 is shown having a threaded end 138. The body 126 of the tip 109 includes a channel 139 which is sized to receive the threaded end 138, and further includes threading 140 to enable mating with the threaded end 138. In FIG. 20B, the threaded end 138 is shown mated with the threading 140 and threaded to contact the encapsulating sensing material 137. Assembly of the temperature probe 10 is therefore easier as the encapsulating sensing material 137 provides feedback as to when the shaft 104 is completely engaged with the tip 109.

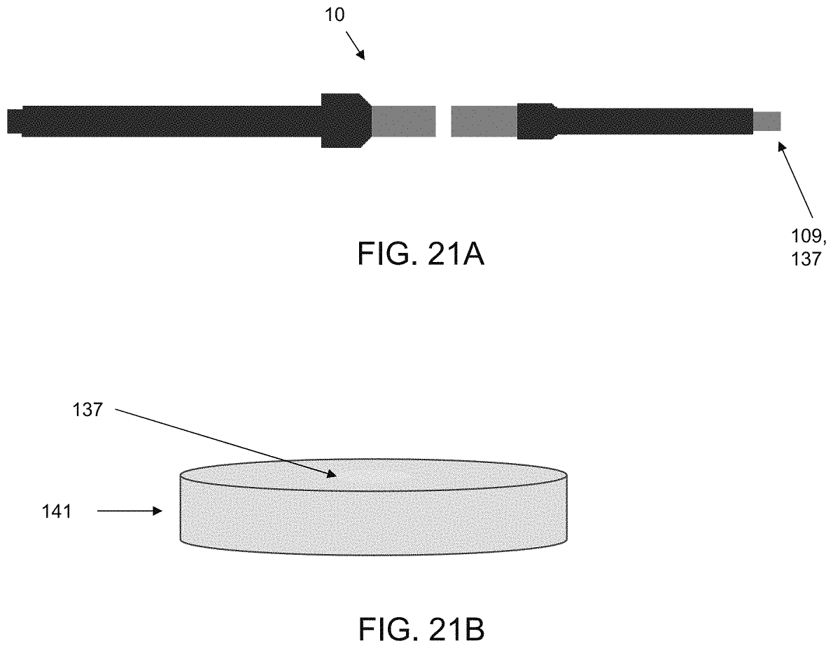

In example embodiments, the encapsulated sensing material 137 can be assembled in a manner similar to that discussed herein with respect to the isolated sensing material 14. For example, the encapsulated sensing material 137 can be secured via adhesive to the tip 109. In example embodiments, the tip 109 can consist of the encapsulated sensing material 137 (FIG. 21A). The encapsulated sensing material 137 can be applied to a measured object 141 (FIG. 21B), in a recess of that object 141, etc. The encapsulated material 137 can be used in the angled applications discussed in respect of FIG. 2.

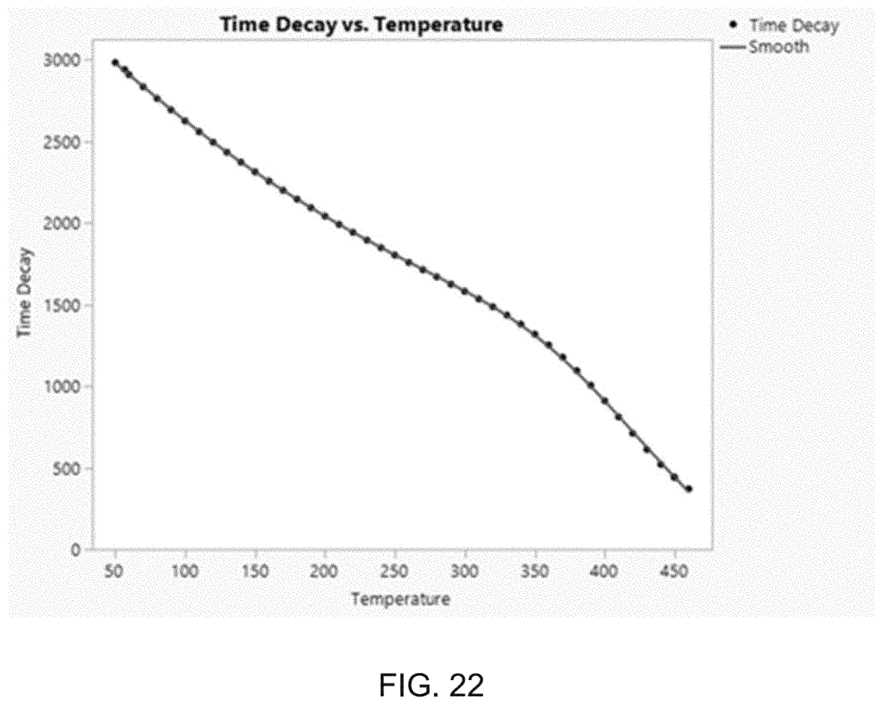

FIG. 22 shows experimental results of testing an example TPiG encapsulated sensing material 137 at different temperatures. In the shown chart, the time constant of the measured TPiG encapsulated sensing material 137 is shown on the vertical axis, and the temperature being measured is shown on the horizontal axis. Importantly, and as discovered, the relationship between the TPiG encapsulated sensing material's time constant and the temperature being measured is monotonic (in this shown graph continuously sloping downward) even at high temperatures, so that a single measurement of the time constant can be correlated to a measured temperature. Moreover, as shown by the slope of the graph, the performance of the example TPiG encapsulated sensing material 137 is relatively consistent, possibly allowing for easier calibration.

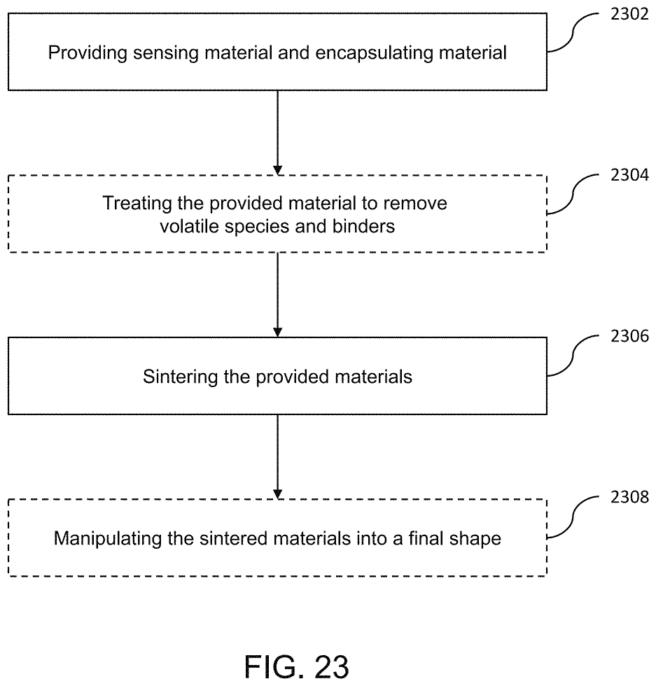

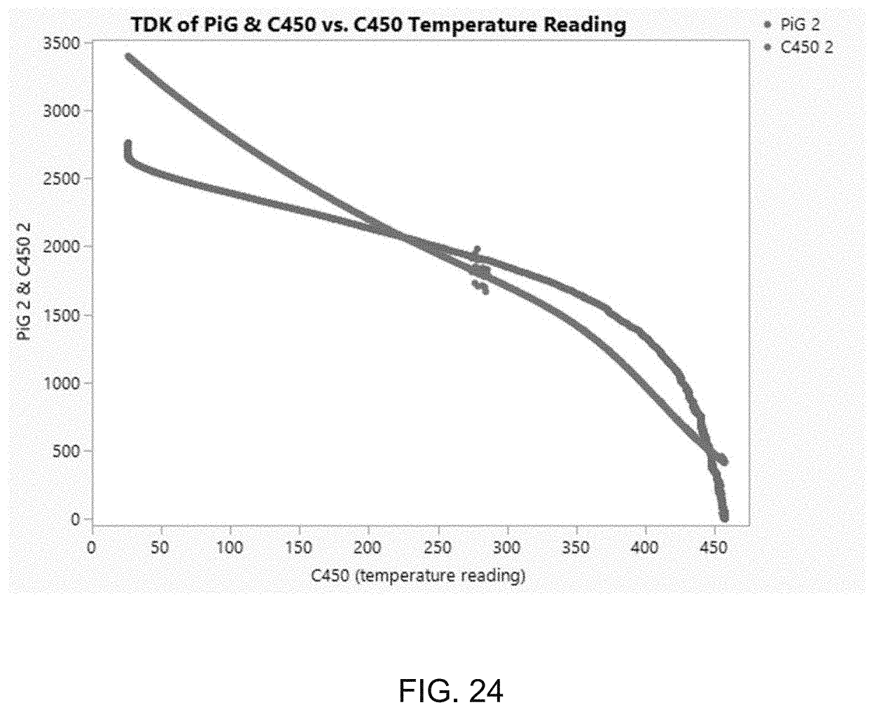

An example method of creating the encapsulated sensing material 137 is shown in FIG. 23. Generally, the sensing material 14 can be encapsulated into the encapsulated sensing material 137 via sintering.

At block 2302, the sensing material 14 and the material used to encapsulate the sensing material 14 to form the encapsulating sensing material 137 are provided. In at least some example embodiments, the sensing material 14 is a thermographic phosphor, and the encapsulating material includes glass, binders, and/or other types of additive materials. The materials can be in a powder, crystal or other non-liquid form, or the materials can include at least some liquid materials.

Providing the materials sensing material 14 and the encapsulating material can, in at least some example embodiments, include molding or manipulating the mixed materials into a final shape or precursor shape. For example, the mixed materials may be provided in a mold in the shape of a wafer or ingot. The molding can require an initial compaction or heating to ensure the mixed materials take the shape of the mold.

Optionally, at block 2304, the sensing material 14 and the encapsulating material can be treated to remove volatile species and binders (whether organic or inorganic). Treating can comprise heat treatment, or other types of treatment. The block 2204 may be unnecessary where the sensing material 14 or the encapsulating material do not include volatile species or binders which cannot be removed via heat treating.

At block 2306, the mixed materials are sintered in a controlled atmosphere to create an optically transparent, non-porous material. The controlled atmosphere can be a vacuum, or controlled to substantially be composed of or include a sufficient amount of inert gases to avoid adverse reactions. In example embodiments, the controlled environment is primarily composed of air. Sintering can result in a non-porous, structured material that will block the diffusion of gasses into the encapsulating sensing material 137 which would otherwise affect the light scattering properties of the encapsulating sensing material 137. Encapsulated sensing material 137 created at least in part by sintering can exhibit high hermiticity, increasing the material's durability in harsh environments.

Optionally, at block 2308, the encapsulating sensing material 137 can be manipulated into a final shape. Manipulating can include, for example, dicing, laser cutting, machining, or other suitable methods known to a person skilled in the art.

Advantageously, the disclosed TPiG encapsulated sensing material 137 may have lower sample to sample variability, allowing for more consistent and reliable temperature probes. The greater sample to sample variability can result from the sintering process, where the thermographic phosphor sensing material 14 does not change its chemical composition during sintering, allowing for greater control of the final composition of the TPiG encapsulated sensing material 137. As a result, sintering can allow for more precise selection of the sensing material 14, to target specific operating environments (e.g., high temperature environments). Moreover, the TPiG encapsulated sensing material 137, owing to its generation via sintering or a similar process, can allow for greater uniformity between TPiG encapsulated sensing material 137 batches as the TPiG encapsulated sensing material 137 results in a more predictable shape and composition compared to other approaches (e.g., a ceramic blend approach). For example, with sintering, different TPiG encapsulated sensing materials 13 may have similar amounts of thermographic phosphor (i.e., sensing material) through the control of the amount of thermographic phosphor input, whereas in a ceramic blend approach, the amount of sensing material may vary as the sensing material amounts may be eroded or created as a result of less predictable or more variable chemical interactions. In another example, with sintering, the final shape of different TPiG encapsulated sensing materials 13 may be more consistent, as sintering may cause the TPiG encapsulated sensing materials 13 to shrink with a greater degree of predictably into a final shape (e.g., the expected shrinking can be accounted for by way of mold creation and material selection).

Additionally, the described sintering process can advantageously allow for selection of encapsulating material that can reduce porosity of the TPiG encapsulated sensing material 137 to a relatively larger extent given the aforementioned stability of the TPiG, increasing the overall robustness of the TPiG encapsulated sensing material 137. For example, materials which have reduced porosity may be selected without regard to the encapsulating material's properties that define chemical interactions with the sensing material. Moreover, given the aforementioned stability of the TPiG, the encapsulating material can be selected to facilitate specific applications, such as a high temperature application. For example, the encapsulating material can be a glass which performs well in high temperature environments. More particularly, in example embodiments, the TPiG encapsulated sensing material 137 can be a sensor with a glass encapsulating material that performs well in environments having a temperature of 450 degrees Celsius, or as high as 750 degrees Celsius, or even as high as 900 degrees Celsius.

Although the above description includes reference to certain specific embodiments, various modifications thereof will be apparent to those skilled in the art. Any examples provided herein are included solely for the purpose of illustration and are not intended to be limiting in any way.

Any drawings provided herein are solely for the purpose of illustrating various aspects of the description and are not intended to be drawn to scale or to be limiting in any way. The scope of the claims appended hereto should not be limited by the preferred embodiments set forth in the above description, but should be given the broadest interpretation consistent with the present specification as a whole. The disclosures of all prior art recited herein are incorporated herein by reference in their entirety.

1. A temperature sensor comprising:
an optical fiber; and
a sensing element, the sensing element encapsulated in a optically transparent, non-porous material thereby isolating the sensing element from a surrounding environment;
wherein the optical fiber is aligned with the sensing element to deliver a source beam to interact with the sensing element and detect a return beam, the return beam exhibiting a temperature dependent property of the sensing element that is measured to determine a temperature of a measured object thermally coupled to the sensing element.

2. The temperature sensor of claim 1, wherein the sensing element is intermixed within the optically transparent, non-porous material.

3. The temperature sensor of claim 2, wherein the optically transparent, non-porous material is glass.

4. The temperature sensor of claim 2, wherein the encapsulated sensing material is a structured material formed at least in part by sintering.

5. The temperature sensor of claim 4, wherein encapsulated sensing element is secured to a tip of a temperature probe using an adhesive.

6. The temperature sensor of claim 1, wherein the encapsulated sensing element is applied to the measured object.

7. The temperature sensor of claim 6, wherein the measured object is a silicon wafer.

8. The temperature sensor of claim 7, wherein the encapsulated sensing element is applied to a downwardly facing surface of a recess in the silicon wafer.

9. The temperature sensor of claim 8, further comprising a rod containing the optical fiber to position the optical fiber in alignment with the encapsulated sensing element.

10. The temperature sensor of claim 1, wherein the sensing element comprises a thermographic phosphor.

11. The temperature sensor of claim 1, wherein the optical fiber is aligned substantially orthogonal to the encapsulated sensing element.

12. The temperature sensor of claim 1, wherein the optical fiber is aligned obliquely relative to the encapsulated sensing element.

13. The temperature sensor of claim 1, wherein a passage in a structural object is aligned with the encapsulated sensing element to permit the optical fiber to optically communicate with the encapsulated sensing element via the passage.

14. The temperature sensor of claim 13, wherein the passage is provided through at least a portion of an electrostatic chuck of a processing chamber.

15. The temperature sensor of claim 1, further comprising a lens to focus the beams emitted and received at the optical fiber.

16. The temperature sensor of claim 1, further comprising a plurality of optical fibers and a plurality of corresponding encapsulated sensing elements to provide multiple temperature sensing locations.

17. The temperature sensor of claim 1, wherein the sensing element is adjacent to an element in a semiconductor processing chamber.

18. The temperature sensor of claim 1, further comprising a light guide for directing light from the optical fiber to the sensing element.

19. A method of encapsulating a phosphor based sensing material, the method comprising:
providing the phosphor based sensing material and an encapsulating material; and
sintering the provided encapsulating material into a optically transparent, non-porous structured material encapsulating the phosphor based sensing material.

20. The method of claim 19, further comprising:
manipulating the encapsulated sensing material into a final shape; or
manipulating the provided materials into a mold defining the final shape.
